(19) United States
(12) Patent Application Publication
(10) Pub. No.: US 2010/0330295 A1
(43) Pub. Date: Dec. 30, 2010

(54) METHOD FOR PROVIDING DUCTILE ENVIRONMENTAL COATING HAVING FATIGUE AND CORROSION RESISTANCE

(75) Inventors: Brian Thomas Hazel, West Chester, OH (US); Ming Fu, Hamilton, OH (US)

Correspondence Address: GENERAL ELECTRIC COMPANY, GE AVIATION, ONE NEUMANN WAY MD F16, CINCINNATI, OH, 45215, US

(73) Assignee: GENERAL ELECTRIC COMPANY

(21) Appl. No.: 12/494,813

(22) Filed: Jun. 30, 2009

(51) Int. Cl. C23C 4/08; B05D 3/02; C23C 16/44; C23C 14/34

(52) U.S. Cl. 427/456; 427/383.7; 427/250; 204/192.11; 204/192.15

(57) ABSTRACT

Method includes providing a superalloy substrate such as a turbine disk, a turbine seal, a turbine blade, a turbine nozzle, a turbine shroud, or a turbine frame or case having an under platform or non-gas path region; and providing a predominantly gamma-prime nickel aluminide intermetallic ductile corrosion and oxidation resistant coating disposed on at least a portion of the substrate. The coating comprises from about 15 to about 30 atomic % aluminum, up to about 20 atomic % chromium, optionally, up to about 30 atomic % of at least one platinum group metal, optionally, up to about 4 atomic % of at least one reactive element, and optionally, up to about 15 atomic % of at least one strengthening element, and a balance being essentially nickel or nickel and at least one of cobalt, iron, or cobalt and iron. A coating precursor composition may be applied to the substrate before or after optional plating with one or more platinum group metals.

### BACKGROUND OF THE INVENTION

This invention relates generally to environmental coatings for gas turbine engine components, and more specifically to methods for providing ductile coatings having good adhesion, strain tolerance, and corrosion resistance on non-gas path regions of turbine components.

Under platform region of blades and non-gas path side of other hot operating parts are subject to corrosive environments at temperatures significantly below that of components such as airfoils within the gas path (<1700° F., 927° C.). This operating environment requires corrosion protection beyond that provided by the superalloy substrate. The corrosion protection is generally achieved by an environmental coating such as an aluminide.

It is known that turbine disk corrosion may result from: 1) deposition of solid particles containing metal sulfates or other metal sulfur oxides plus reducing agents onto the disk; and 2) reaction of the deposited particles with the disk alloy at elevated temperatures to form reduced metal sulfides covered by air-impermeable fused solid particles.

Although the environmental coating can provide improved corrosion resistance, it can cause problems with the mechanical property performance of the part. For example, aluminide coatings suffer from low ductility at temperatures below their ductile-to-brittle transition temperature (˜1600° F., 871° C.). This lack of ductility results in early fatigue crack initiation when compared to the substrate metal. Thus coatings which may be used on components or regions of components subjected to higher operating temperatures may not be suitable for use on turbine blade shanks or disks which are not generally directly exposed to the gas path.

Other approaches to corrosion protection include the use of layered paints. Known layered paints are believed to rely on a mechanical adhesion to a grit-blasted surface. However, such layered paints have shown susceptibility to spallation during engine operation due to high interfacial strains during thermal transient engine conditions.

Another proposed solution to improve corrosion resistance is a platinum-based coating as taught in U.S. Pat. No. 6,565,931. The disclosed coating forms a gamma/gamma′ structure similar to the superalloy of the substrate. However, evaluation of the coating has revealed insufficient corrosion protection.

Application of a vapor phase chromide coating as taught in U.S. Pat. No. 6,283,715 may raise concerns on dovetail mating surfaces because of ineffective masking procedures or incompatibility with internal or airfoil coatings.

U.S. Pat. No. 7,364,801 discloses an environmental coating that is predominantly a solid solution phase of preferably gamma-Ni matrix, gamma-Co matrix, or a mixture of nickel and cobalt. As taught, this coating may include aluminum additions in the range of about 4 to 8 weight percent to enhance corrosion and oxidation resistance.

Accordingly, it would be desirable to provide a coating and coating process that supplies corrosion protection, sufficient ductility, is compatible with other coatings on the component and/or capable of local application.

### BRIEF DESCRIPTION OF THE INVENTION

The above-mentioned need or needs may be met by exemplary embodiments directed to methods for providing a ductile corrosion and oxidation resistant coating disposed on at least a non-gas path region of a substrate, which may be the under platform region of a turbine blade. The superalloy substrate comprises a turbine disk, a turbine seal or a turbine blade, turbine nozzle, turbine shroud, or turbine cases and frames having an under platform or non-gas path region. The ductile coating is predominately of gamma-prime nickel aluminide intermetallic. As deposited, the coating comprises from about 15 to about 30 atomic % aluminum, up to about 20 atomic % chromium, optionally, up to about 30 atomic % of a platinum group metal selected from platinum, ruthenium, rhodium, palladium, osmium, and iridium, optionally, up to about 4 atomic % of at least one reactive element selected from zirconium, hafnium, yttrium, silicon, lanthanum, and mixtures thereof, and optionally, up to about 15 atomic % of at least one strengthening element selected from tantalum, tungsten, molybdenum, rhenium, and mixtures thereof, and a balance being essentially nickel or nickel and at least one of cobalt, iron, or cobalt and iron.

### BRIEF DESCRIPTION OF THE DRAWINGS

The subject matter which is regarded as the invention is particularly pointed out and distinctly claimed in the concluding part of the specification. The invention, however, may be best understood by reference to the following description taken in conjunction with the accompanying drawing figures in which:

FIG. 1 is a schematic view of one embodiment of a portion of a turbine section of a gas turbine engine; and

FIG. 2 is a schematic view of one embodiment of a protective coating deposited on a rotor component.

### DETAILED DESCRIPTION OF THE INVENTION

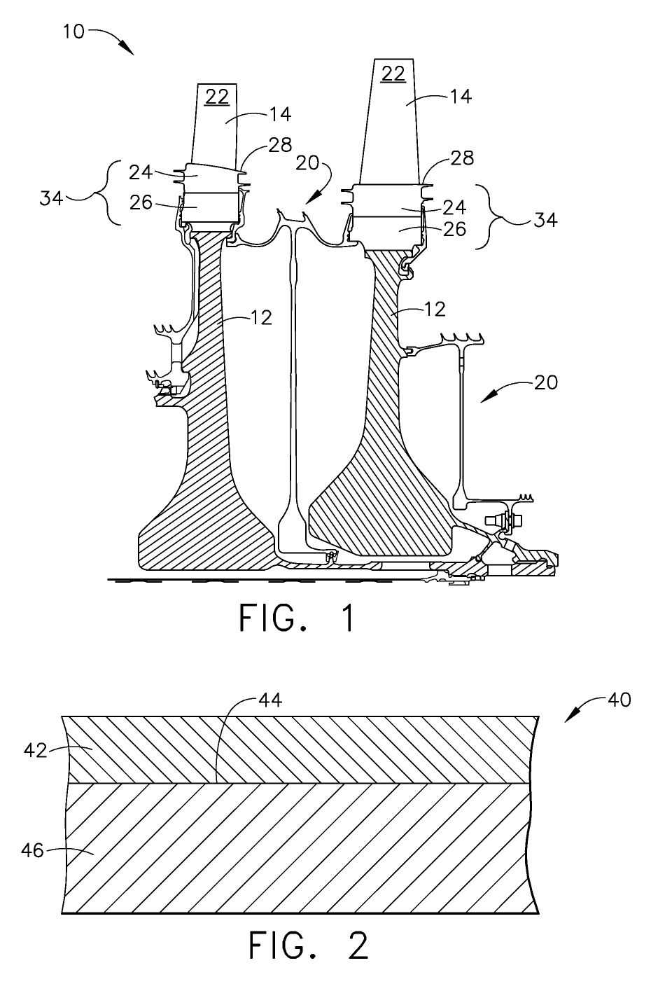

Referring to the drawings wherein identical reference numerals denote the same elements throughout the various views, FIG. 1 represents a portion of a turbine section 10 of a gas turbine engine. The depicted portion contains two disks 12 on which turbine blades 14 rotate about an axis, and therefore are rotating components of the turbine section 10. Non-rotating (static) components of the turbine section 10 are not shown in FIG. 1, but are understood to include a shroud that surrounds the disks 12 in close proximity to the tips of the blades 14, and nozzle assemblies disposed between the disks 12 with vanes that direct the flow of combustion gases through the blades 14. Seal elements 20 are shown assembled to the disks 12 and cooperate with surfaces of the static components to form seals that reduce secondary flow losses between the rotating and static components of the turbine section 10. As is common with gas turbine engines and other turbomachinery, the blades 14 (and vanes) may be formed of equiaxed, directionally solidified (DS), or single-crystal (SX) superalloys, while the disks 12 and seal elements 20 are generally formed of polycrystalline superalloys that undergo carefully controlled forging, heat treatments, and surface treatments to achieve desirable grain structures and mechanical properties.

Blade 14 includes an airfoil 22 against which the flow of hot combustion gas impinges during service operation, a downwardly extending shank 24, and an attachment in the form of a dovetail 26 which attaches the gas turbine blade 14 to the gas turbine disk 12. A platform 28 extends transversely outwardly at a location between the airfoil 22 and the shank 24 and dovetail 26. The portion of the blade 14 disposed beneath the platform 28 is herein collectively termed the “under platform region” 34.

FIG. 2 schematically represents a portion of a coated article 40 having an oxidation and corrosion-resistant environmental coating 42 deposited on a surface region 44 of a substrate 46, which may be any portion of the disks 12, seal elements 20, and/or any portion of the under platform region 34 of FIG. 1. Other exemplary coated articles include turbine blades, nozzles, turbine shrouds, turbine frame or case having, in general, a non-gas path region.

By way of example and not limitation, one nickel-base superalloy that may be used is known in the art as Rene′88DT, which has a nominal composition, by weight, of about 13% cobalt, about 16% chromium, about 4% molybdenum, about 3.7% titanium, about 2.1% aluminum, about 4% tungsten, about 0.70% niobium, about 0.015% boron, about 0.03% zirconium, and about 0.03% carbon, balance nickel and minor impurities.

In the art it is known to provide the airfoil 12 and platform 14 with a coating 42 which protects the underlying regions from hot gas flowing through the turbine. Additionally, it has been discovered that areas not within the gas flow path, particularly in the under platform region and turbine disks, require protective environmental coatings for corrosion resistance.

Exemplary embodiments disclosed herein provide protective environmental coatings for superalloy substrates. The exemplary coatings are particularly suited to survive in cyclic thermal environments. The exemplary embodiments exhibit sufficient strength and ductility to minimize cracking, and thus minimize component failure. Exemplary embodiments disclosed herein are particularly suitable as coatings on substrates, or portions of substrates, not directly in the gas flow path. Thus, the coating is suitable for use at temperatures generally lower than those encountered by, for example, the airfoil portion of a turbine blade.

Exemplary coatings disclosed herein exhibit adequate strain tolerance capability (i.e., tensile ductility) to minimize coating cracking that would otherwise result in fatigue failure due to propagation of brittle coating cracks. Exemplary embodiments disclosed herein further form protective oxide for corrosion resistance.

Exemplary embodiments disclosed herein may be considered as modified compositions derived from a base composition including about 75 at % Ni and 25 at % Al (Ni3Al), wherein aluminum is present in amounts such that the coating may be provided as predominantly the gamma-prime (gamma′) phase. By “predominantly gamma prime” it is meant greater than 75 volume % of the coating is a gamma prime phase. In certain embodiments, the gamma phase may be present in amounts up to about 25 volume %. Exemplary embodiments disclosed herein may include aluminum at levels such that the coating is predominantly gamma′ and/or discontinuous in a beta phase.

Exemplary embodiments disclosed herein may further include chromium in amounts up to about 20 atomic percent for corrosion improvement. An exemplary composition for use as a coating includes about 75 atomic % (nickel and chromium), where chromium is present up to about 18 atomic %, and up to about 25 atomic % aluminum or (aluminum plus hafnium).

Exemplary embodiments disclosed herein may include additional elements for environmental resistance and/or strengthening. For example, additional elements such as zirconium (Zr), hafnium (Hf), yttrium (Y), silicon (Si), lanthanum (La), singly or in combination, may be substituted for all or a portion of the aluminum in the base composition. Additionally, exemplary embodiments may include strengthening elements such as tantalum (Ta), tungsten (W), molybdenum (Mo) and rhenium (Re), singly or in combination. An exemplary composition for use as a coating includes about 75 at % nickel, about 25 at % (aluminum plus hafnium). Other exemplary coatings include at least 6 at % and not more than about 25 at % aluminum.

Exemplary embodiments disclosed herein may optionally include Pt or other platinum group metal, as substituted for nickel in the base composition. As used herein, “platinum group metal” denotes platinum, ruthenium, rhodium, palladium osmium or iridium. An exemplary embodiment includes a Ni—Al—Pt—Hf—Cr gamma prime coating.

Further, in exemplary embodiments, all, or a portion of nickel in any of the coatings provided herein may be substituted by Co and Fe, singly or in combination.

The disclosed coating compositions may be applied to appropriate regions of a substrate by chemical vapor deposition (CVD), physical vapor deposition (PVD), (e.g., ion plasma/cathodic arc), plating, thermal spray, diffusion processes, or any suitable technique. Exemplary embodiments may include optional platinum or platinum group metal plating prior to or after coating with a precursor composition such that platinum (or platinum group metal or metals) are introduced into an environmental coating. “Precursor composition” denotes a preselected composition that in conjunction with the platinum group metal(s), if utilized, will form the desired coating on the substrate.

Exemplary embodiments may include coatings applied or deposited as a single homogeneous layer. Alternately, exemplary coatings may be applied or deposited in discrete layers. Coatings applied or deposited in discrete layers may additionally require heat treatments to diffuse the layers as is understood by those having skill in the art. Optionally, exemplary coatings may include layers having compositional gradients. In other exemplary embodiments, the part or component to be coated may be sufficiently masked to limit coating in the corrosion prone portions only. In other exemplary embodiments, the part or component may be shot peened or otherwise mechanically processed before or after coating depending on the desired result.

An exemplary embodiment is directed to a predominately gamma-prime nickel aluminide intermetallic coating including from about 15 to about 30 atomic % aluminum, up to about 20 atomic % chromium, optionally, up to about 30 atomic % of a platinum group metal selected from platinum, ruthenium, rhodium, palladium, osmium, or iridium, optionally, up to about 4 atomic % of at least one reactive element selected from zirconium, hafnium, yttrium, silicon, or lanthanum, and mixtures thereof, and optionally, up to about 15 atomic % of at least one strengthening element selected from tantalum, tungsten, molybdenum, or rhenium, and mixtures thereof, and a balance being essentially nickel or nickel and at least one of cobalt, iron, or cobalt and iron.

In an exemplary embodiment, the intermetallic coating consists essentially of about 16-25 atomic % aluminum, about 3-11 atomic % chromium, up to about 6 atomic % of at least one platinum group metal, up to about 3 atomic % hafnium, the balance being essentially nickel.

In an exemplary embodiment, the intermetallic coating includes about 17-21 atomic % aluminum, about 4-12 atomic % chromium, about 3-10 atomic % of the selected platinum group metal(s), up to about 4 atomic % of the selected reactive element(s), up to about 15 atomic % of the selected strengthening element(s), the balance being essentially nickel.

In an exemplary embodiment, the intermetallic coating includes about 17-21 atomic % aluminum, about 4-12 atomic % chromium, up to about 4 atomic % of the selected reactive element(s), up to about 15 atomic % of the selected strengthening element(s), substantially 0 atomic % of the platinum group metal(s), the balance being essentially nickel.

In an exemplary embodiment, the intermetallic coating includes about 15-30 atomic aluminum %, about 3-11 atomic % chromium, platinum in an amount up to about 6 atomic %, hafnium in an amount up to about 3 atomic %, the balance being essentially nickel

Exemplary embodiments include coated articles. In particular, articles adapted for thermal cycles may benefit from the coatings disclosed herein. Coated substrates or portions of substrates not directly exposed to the gas path may be sufficiently protected by the ductile coatings disclosed herein. Additionally, embodiments disclosed herein are either compatible with coatings used on other areas of the component, are capable of local application, or both.

### EXAMPLES

A nominal Ni-20Al-3Cr-7Pt-0.6Hf predominantly gamma prime coating was produced by ion plasma deposition (cathodic arc) at a temperature of less than 600° C. on a Rene′88DT substrate flat panel samples to a thickness of about 1.0-1.5 mils (about 25.4-38.1 microns). Exemplary samples underwent seven corrosion test cycles. The samples were cut up for analysis. Analysis of the samples demonstrated that the corrosion was restricted to the coating only.

A Ni—Al—Cr—Pt—Hf coating has been produced by platinum plating followed by ion plasma deposition (cathodic arc) of Ni—Al—Cr—Hf and optionally heat treatment interdiffusing at 2000° F. (about 1093° C.).

A Ni(16-25 atomic %)-Al(3-11 atomic %)-Cr(6 atomic %)-Pt—Hf coating has been demonstrated.

Certain exemplary embodiments include a coating formed by providing platinum, and/or a platinum group metal by plating a selected portion of the substrate and thereafter applying a precursor coating composition on the plating. A suitable heat treatment may be utilized for diffusion to form the coating. In certain exemplary embodiments, physical vapor or other suitable deposition techniques is used to apply the precursor coating composition.

Certain other embodiments disclosed herein include a coating formed by applying a precursor coating composition on a suitable substrate, and thereafter providing platinum and/or another platinum group metal over the precursor coating composition. A suitable heat treatment may be utilized to form the coating.

Certain other embodiments include a coated article having any of the coatings disclosed herein disposed on at least a pre-selected portion of the substrate.

Exemplary coatings may comprise a thickness of from about 5 to about 100 microns. Other exemplary coatings may comprise a thickness of from about 10 to about 50 microns. Still other exemplary coatings may comprise a thickness of from about 25 to about 40 microns.

It is believed that the exemplary coatings disclosed herein may be utilized in repair processes for in-service parts and components. An exemplary repair method includes: providing a component having previously been in-service and having an environmental coating thereon in need of repair; stripping at least a portion of the coating; and providing an exemplary coating as set forth herein.

A predominantly gamma′ coating composition that is modified with platinum or other platinum group metal or metals is expected to provide ductility similar to a platinum-only coating by avoiding continuous formation of the beta nickel aluminide phase, but with improved environmental resistance. An increased chromium level provides added corrosion benefit. Additionally, the disclosed coatings provide increased oxidation protection as compared to chromide or platinum-only coatings in regions where corrosion does not occur.

Exemplary coatings disclosed herein here have good adhesion to the substrate due to metallurgical bonding therebetween. The exemplary coatings exhibit good strain tolerance. Exemplary embodiments disclosed herein provide corrosion resistance. Thus, the predominately gamma-prime (gamma′) coatings disclosed herein provide good adhesion, strain tolerance, and corrosion capability in particular for turbine components or regions not subject to the extreme temperatures of the gas path.

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A method comprising:
providing a substrate comprising a superalloy, wherein the substrate comprises at least one member selected from the group consisting of: a turbine disk, a turbine seal, a turbine blade, a turbine nozzle, a turbine shroud, or a turbine frame or case having an under platform or non-gas path region; and
providing a ductile corrosion and oxidation resistant coating disposed on at least a portion of the substrate, the coating being predominately of gamma-prime nickel aluminide intermetallic wherein the coating comprises from about 15 to about 30 atomic % aluminum, up to about 20 atomic % chromium, optionally, up to about 30 atomic % of at least one platinum group metal selected from platinum, ruthenium, rhodium, palladium, osmium, or iridium, optionally, up to about 4 atomic % of at least one reactive element selected from zirconium, hafnium, yttrium, silicon, or lanthanum, and mixtures thereof, and optionally, up to about 15 atomic % of at least one strengthening element selected from tantalum, tungsten, molybdenum, or rhenium, and mixtures thereof, and a balance being essentially nickel or nickel and at least one of cobalt, iron, or cobalt and iron.

2. The method according to claim 1 wherein the coating includes the at least one platinum group metal in an amount up to about 30 atomic %, and wherein providing the ductile and corrosion resistant coating disposed on at least the portion of the substrate includes:
providing a sufficient amount of the at least one platinum group metal on at least the portion of the substrate;
thereafter, using a suitable technique to apply a coating precursor composition on the platinum group metal; and
optionally thereafter, subjecting the substrate to an appropriate heat treatment to form the coating from the coating precursor composition, and the at least one platinum group metal;
wherein the coating precursor composition comprises sufficient amounts of aluminum, chromium, hafnium, and a balance being nickel to result in a coating comprising aluminum in an amount of from about 15 to about 30 atomic %, chromium in an amount up to about 20 atomic %, platinum in an amount up to about 30 atomic %, hafnium in an amount up to about 3 atomic % and a balance being nickel.

3. The method according to claim 2 wherein the suitable technique is at least one technique selected from chemical vapor deposition (CVD), physical vapor deposition (PVD), plating, thermal spray, or diffusion processes.

4. The method according to claim 3 further comprising:
subjecting the coated substrate to a suitable heat treatment.

5. The method according to claim 4 wherein the heat treatment includes interdiffusing at about 2000° F. (about 1093° C.).

6. The method according to claim 1 wherein the coating includes the at least one platinum group metal in an amount up to about 30 atomic %, and wherein providing the ductile and corrosion resistant coating disposed on at least the portion of the substrate includes:
using a suitable technique to apply a coating precursor composition on at least the portion of the substrate;
thereafter, providing a sufficient amount of the at least one platinum group metal on the coating precursor composition; and
optionally thereafter, subjecting the substrate to an appropriate heat treatment to form the coating from the coating precursor composition and the at least one platinum group metal;
wherein the coating precursor composition comprises sufficient amounts of aluminum, chromium, hafnium, and a balance being nickel to result in a coating comprising aluminum in an amount of from about 15 to about 30 atomic %, chromium in an amount up to about 20 atomic %, platinum in an amount up to about 30 atomic %, hafnium in an amount up to about 3 atomic % and a balance being nickel.

7. The method according to claim 6 wherein the suitable technique is at least one technique selected from chemical vapor deposition (CVD), physical vapor deposition (PVD), plating, thermal spray, or diffusion processes.

8. The method according to claim 7 wherein providing the ductile and corrosion resistant coating disposed on at least the portion of the substrate includes:
providing a coating precursor composition comprising a sufficient amount of aluminum, chromium, hafnium, and a balance being nickel on at least the portion of the substrate using a physical vapor deposition technique; and
providing the at least one platinum group metal by a plating technique to result in a coating comprising aluminum in an amount of from about 15 to about 30 atomic %, chromium in an amount up to about 20 atomic %, platinum in an amount up to about 30 atomic %, hafnium in an amount up to about 3 atomic % and a balance being nickel.

9. The method according to claim 8 further including subjecting the coated substrate to a suitable heat treatment.

10. The method according to claim 9 wherein the heat treatment includes interdiffusing at about 2000° F. (about 1093° C.).

11. The method according to claim 1 wherein providing a substrate comprises providing a turbine blade having an under platform region, and wherein the at least a portion of the substrate includes the under platform region.

12. The method according to claim 1 wherein providing a substrate comprises providing a turbine disk including the non-gas path region.

13. The method according to claim 1 wherein providing a substrate comprises providing at least a selected turbine member component having been used in service.

14. The method according to claim 1 wherein providing a ductile corrosion and oxidation resistant coating includes providing a plurality of compositional gradient layers to form the coating.
